(19) United States
(12) Patent Application Publication
(10) Pub. No.: US 2026/0363138 A1
(43) Pub. Date: Nov. 12, 2026

(54) MICROELECTRONIC DEVICES COMPRISING AN ANNEALED PHOTON ABSORPTIVE MATERIAL AND TRANSPARENT MATERIALS AND RELATED METHODS

(71) Applicant: Micron Technology, Inc., Boise, ID (US)

(72) Inventors: Thomas Peterson, Boise, ID (US); Adam W. Saxler, Boise, ID (US); Sundaravadivel Rajarajan, San Jose, CA (US); Kyubong Jung, Boise, ID (US); Erica A. Ellingson, Boise, ID (US); Chanse Hungerford, Boise, ID (US); Nicholas R. Tapias, Boise, ID (US); Kamal M. Karda, Boise, ID (US)

(21) Appl. No.: 19/655,520

(22) Filed: Apr. 22, 2026

Related U.S. Application Data
(60) Provisional application No. 63/802,407, filed on May 8, 2025.

(51) Int. Cl. H10W 74/10; H10B 80/00; H10D 80/30; H10W 74/01; H10W 74/40; H10W 74/47; H10W 90/26

(52) U.S. Cl. CPC H10W 74/147; H10W 74/01; H10W 74/134; H10W 74/47; H10W 74/481; H10B 80/00; H10D 80/30; H10W 90/26

(57) ABSTRACT

A microelectronic device comprises a first region adjacent to a second region, the first region comprising an array region and the second region comprising a non-array region. An annealed photon absorptive material is adjacent to the first region and the second region. A first transparent material is vertically adjacent to the annealed photon absorptive material and a second transparent material is vertically adjacent to the first transparent material. An interface between the first transparent material and the second transparent material exhibits grain boundary differences. A memory device and a method of forming a microelectronic device are also disclosed.

### CROSS-REFERENCE TO RELATED APPLICATIONS

This application claims the benefit under 35 U.S.C. § 119(e) of U.S. Provisional Patent Application Ser. No. 63/802,407, filed May 8, 2025, the disclosure of which is hereby incorporated herein in its entirety by this reference.

### TECHNICAL FIELD

This disclosure relates to microelectronic devices and methods of forming the same. More specifically, the disclosure relates to microelectronic devices including an annealed photon absorptive material and a cap structure and methods of forming the microelectronic device.

### BACKGROUND

Microelectronic devices (e.g., NAND, DRAM, etc.), at ever reducing dimensions, are reaching the limitations of chemical vapor deposition (CVD) and atomic layer deposition (ALD) gap fill capabilities. Ever increasing demands for reducing power consumption and footprint of microelectronic devices (e.g., periphery sensing devices) has necessitated the introduction of temperature-sensitive high-k materials. However, structural improvements in microelectronic devices exceed the compatibility of high-k materials as gap-fill materials and conventional methods of deposition (e.g., CVD, ALD, etc.) utilized to deposit such materials in gaps.

There is an ever-growing need for high performing microelectronic devices. The performance of a microelectronic device crucially depends on highly conductive structures (e.g., gap-fills). A low performance deposition of gap-fill materials between features (e.g., memory pillars of a memory device) results in formation of voids that eventually affects the conductivity of the microelectronic device to a great extent. Due to incompatibility of high-k materials and limitations of current methods of deposition, conventionally formed gaps fills are not free of voids and do not possess required conductivity for high performing microelectronic devices.

### BRIEF DESCRIPTION OF THE DRAWINGS

FIGS. 1A and 1B are simplified cross-sectional views of microelectronic devices according to embodiments of the disclosure.

FIGS. 2A and 2B are partial cross-sectional views of microelectronic devices according to embodiments of the disclosure.

FIG. 3 is a simplified flow diagram of a method of forming a microelectronic device according to embodiments of the disclosure.

FIGS. 4, 5A, 5B, 6, and 7 are partial cross-sectional views of a microelectronic device during process stages of a method of forming the microelectronic device.

FIG. 8 is a simplified partial schematic view of a microelectronic device according to embodiments of the disclosure.

FIG. 9 is a simplified schematic view of an electronic system including one or more microelectronic devices according to embodiments of the disclosure.

FIG. 10 is a simplified schematic view of an electronic system including one or more microelectronic devices according to embodiments of the disclosure.

### DETAILED DESCRIPTION

The illustrations presented herein are not actual views of any microelectronic device, or any component thereof, but are merely idealized representations, which are employed to describe embodiments of the disclosure.

As used herein, the singular forms following “a,” “an,” and “the” are intended to include the plural forms as well, unless the context clearly indicates otherwise.

As used herein, the term “base material” means and includes a substrate or construction upon which additional materials are formed. The base material may be a semiconductor substrate, a base semiconductor layer on a supporting structure, a metal electrode, or a base material having one or more materials, layers, structures, or regions formed thereon. The materials on the base material may include, but are not limited to, semiconductive materials, insulating materials, conductive materials, etc. One or more materials may be thermally sensitive. The base material may be a conventional silicon substrate or other bulk substrate comprising a layer of semiconductive material. As used herein, the term “bulk substrate” means and includes not only silicon wafers, but also silicon-on-insulator (“SOI”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped.

As used herein, the term “may” with respect to a material, structure, feature, or method act indicates that such is contemplated for use in implementation of an embodiment of the disclosure, and such term is used in preference to the more restrictive term “is” so as to avoid any implication that other compatible materials, structures, features, and methods usable in combination therewith should or must be excluded.

As used herein, any relational term, such as “first,” “second,” “top,” “bottom,” “upper,” “lower,” “above,” “beneath,” “side,” “upward,” “downward,” etc., is used for clarity and convenience in understanding the disclosure and accompanying drawings, and does not connote or depend on any specific preference or order, except where the context clearly indicates otherwise. For example, these terms may refer to an orientation of elements of any microelectronic device when utilized in a conventional manner. Furthermore, these terms may refer to an orientation of elements of any microelectronic device as illustrated in the drawings.

As used herein, the term “substantially” in reference to a given parameter, property, or condition means and includes to a degree that one skilled in the art would understand that the given parameter, property, or condition is met with a small degree of variance, such as within acceptable manufacturing tolerances. By way of example, depending on the particular parameter, property, or condition that is substantially met, the parameter, property, or condition may be at least about 50.0% met, such as between about 50.0% and about 55.0% met, between about 55.0% and about 60.0% met, between about 60.0% and about 65.0% met, between about 65.0% and about 70.0% met, between about 70.0% and about 75.0% met, between about 75.0% and about 80.0% met, between about 85.0% and about 90.0% met, at least about 95.0% met, at least about 99.0% met, or even at least about 99.9% met.

As used herein, the term “about” used in reference to a given parameter is inclusive of the stated value and has the meaning dictated by the context (e.g., it includes the degree of error associated with measurement of the given parameter, as well as variations resulting from manufacturing tolerances, etc.). For example, “about” or “approximately” in reference to a numerical value may include additional numerical values within a range of from 90.0 percent to 108.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, the term “atoms/cm³” is used in reference to a number of atoms of a material (e.g., a dopant material) per cubic centimeter of a fill material (e.g., a dielectric fill material).

As used herein, the term “J/cm²” is used in reference to energy of radiation (e.g., a laser emission) emitted on a square centimeter of an upper surface of a microelectronic device.

As used herein, the term “photon absorptive material” is used in reference to a material that is formulated to absorb energy of incident radiation (e.g., electromagnetic waves) and convert the energy to thermal energy, which is then absorbed by the material.

As used herein, the term “transparent material” is used in reference to a material that is formulated to internally reflect an incident radiation within the material. Radiation (e.g., light) emitted on the transparent material passes through the transparent material and travels through a thickness of the transparent material and then impacts a boundary between the transparent material and another material (e.g., a photon absorptive material) directly adjacent to the transparent material. Upon impact with the boundary of the transparent material, the radiation may be reflected (e.g., reflected internally) into the transparent material at a different wavelength (e.g., a lower wavelength) or the radiation may absorb in the photon absorptive material. The reflected radiation travels back through the thickness of the transparent material and impacts a boundary between the transparent material and another material (e.g., air) directly adjacent to the transparent material and again reflects back into the transparent material at a different wavelength. The internal reflection of the radiation continues until the radiation is substantially absorbed within the adjacent photon absorptive material.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

The following description provides specific details, such as material types and processing conditions in order to provide a thorough description of embodiments described herein. However, a person of ordinary skill in the art will understand that the embodiments disclosed herein may be practiced without employing these specific details. Indeed, the embodiments may be practiced in conjunction with conventional fabrication techniques employed in the semiconductor industry. In addition, the description provided herein does not form a complete description of a process flow for manufacturing microelectronic devices. The structures described below do not form complete microelectronic devices. Only those process acts and structures necessary to understand the embodiments described herein are described in detail below. Additional acts to form a complete microelectronic device described herein may be performed by conventional techniques.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

According to embodiments disclosed herein, microelectronic devices and methods of forming thereof are disclosed. The microelectronic device includes one or more photon absorptive materials and one or more transparent materials. A first transparent material may form a cap on the microelectronic device (e.g., on a first photon absorptive material). The first transparent material and a second transparent material vertically adjacent to the first transparent material form a cap structure on the microelectronic device.

The cap enables annealing of regions of an underlying material (e.g., a photon absorptive material) vertically adjacent to (e.g., below) the cap without modifying an anneal tool to produce higher temperatures in other regions (e.g., heat sensitive regions) of the microelectronic device. The underlying material may, therefore, be more effectively annealed by exposing the material to a higher effective temperature than that produced by a conventional anneal tool. In other words, the underlying material may be effectively annealed at a lower temperature than that produced by a conventional anneal tool. The annealing of the photon absorptive material at higher effective temperatures allows the microelectronic device to exhibit greater dopant activation (e.g., dopant activation in pillar regions), reduced surface reflow and roughness (e.g., in the photon absorptive material), and reduced air gaps (e.g., air gaps between the photon absorptive material and a vertically adjacent region thereto) compared to a conventional microelectronic device that lacks the cap. The cap may enable underlying regions of the microelectronic device to be annealed (e.g., selectively annealed) while other regions (e.g., regions not underlying the cap) are not annealed. For instance, the cap may be formed over only specific regions of the microelectronic device that are to be subsequently annealed to achieve increased dopant activation and reduced roughness in the specific regions following the anneal.

The method includes annealing (e.g., laser annealing) the photon absorptive material (e.g., a polysilicon material) below the cap to achieve the increased dopant activation and reduced roughness. By heating the specific regions of the microelectronic device when the materials of the regions are present in an upper location of the microelectronic device, the entire microelectronic device does not need to be heated. Since the regions to be heated are in the upper location of the microelectronic device, the anneal tool used to conduct the heating may be operated at a lower temperature.

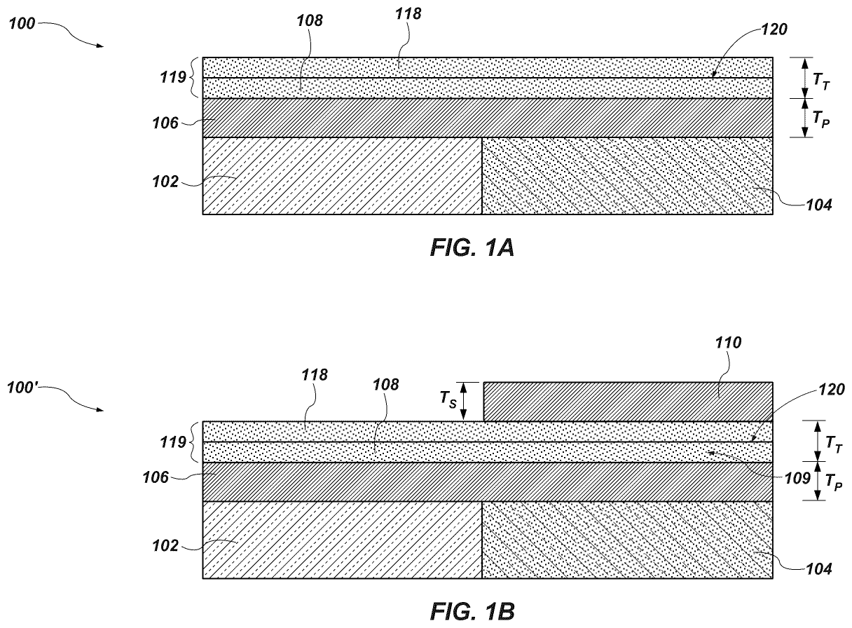

FIGS. 1A and 1B illustrate simplified cross-sectional views of a microelectronic device 100, 100′, formed according to embodiments of the disclosure. The microelectronic device 100, 100′ include a first region 102 and a second region 104, with the first and second regions 102, 104 being adjacent to (e.g., laterally adjacent to) each other. The microelectronic device 100, 100′ may be disposed on a base material (e.g., a substrate) (not shown). The first region 102 may include, for example, an array region of the microelectronic device 100, 100′. The second region 104 may include, for example, a complementary metal oxide semiconductor (CMOS) region, a peripheral region, a registration mark region, or a scribe region. The first region 102 may include features thereon and therein, such as memory pillars, contacts, etc. An annealed photon absorptive material 106 (e.g., an annealed photon absorptive material) and a transparent material 108 are vertically adjacent to the first region 102 and the second region 104, as shown in FIGS. 1A and 1B. The first transparent material 108 forms a cap, the presence of which enables vertically adjacent (e.g., underlying) portions of the microelectronic device 100, 100′ to be heated to the higher effective temperature. The higher effective temperature within the microelectronic device 100, 100′ may be achieved without modifying a tool (e.g., an anneal tool) to be configured to heat to the higher temperature. The cap enables underlying materials to be annealed without annealing other regions of the microelectronic device, such as those not vertically adjacent to (e.g., below) the cap. In addition, the cap allows existing anneal tools to be used to achieve the increased dopant activation and reduced roughness in materials vertically adjacent to the cap. The first transparent material 108 forms a portion of a cap structure 119. A second transparent material 118 overlies the first transparent material 108 and forms another portion of the cap structure 119. FIGS. 1A and 1B show only a portion of a microelectronic device 100, 100′ according to embodiments of the disclosure, with additional features omitted for convenience and simplification.

An additional photon absorptive material 110 may optionally overlie a portion 109 of the first transparent material 108 vertically adjacent (e.g., above) the second region 104, as shown in the microelectronic device 100′ of FIG. 1B. The optional photon absorptive material 110 may substantially block radiation from penetrating into the second region 104, which may include a thermally sensitive material. In such embodiments, the optional photon absorptive material 110 advantageously protects the second region 104 from overexposure to the radiation.

The annealed photon absorptive material 106 overlies the first region 102 and the second region 104. The annealed photon absorptive material 106 may be formed of a photon absorptive material formulated to absorb energy of radiation at a desired wavelength and convert the energy to thermal energy which anneals the photon absorptive material to the annealed photon absorptive material 106.

The energy absorbed by the material may be generated by a radiation source, such as a laser. The laser may, for example, be used to anneal materials of the microelectronic device 100, 100′. The annealed photon absorptive material 106 may be formed of a single material, as shown in FIGS. 1A and 1B, or of multiple materials. The annealed photon absorptive material 106 may be formed from and include a silicon material, such as one or more of an amorphous silicon material, a polysilicon material, a crystalline silicon material, or a combination thereof. The annealed photon absorptive material 106 may be doped or undoped. If the annealed photon absorptive material 106 includes a single material, the annealed photon absorptive material 106 may be formed of and include about 100% of the amorphous silicon material, the polysilicon material, or the crystalline silicon material. In some embodiments, the annealed photon absorptive material 106 is polysilicon.

If the annealed photon absorptive material 106 includes more than one material, the annealed photon absorptive material 106 may be formed of and include between about 0 percent (e.g., 0% w/w) and about 100 percent of two or more of the silicon materials (e.g., the amorphous silicon material, the polysilicon material, the silicon oxide material, or the crystalline silicon material), such as between about 1 percent and about 20 percent, between about 20 percent and about 40 percent, between about 40 percent and about 60 percent, between about 60 percent and about 80 percent, and between about 80 percent and about 100 percent. For example, the annealed photon absorptive material 106 may include about 50% amorphous silicon material, about 30% polysilicon material, and about 20% crystalline silicon material or any other combination of weight percentages of two or more of the silicon materials.

The annealed photon absorptive material 106 may be formulated to absorb energy of radiation at a wavelength between about 100 nm and about 600 nm, such as between about 100 nm and about 150 nm, between about 150 nm and about 200 nm, between about 200 nm and about 250 nm, between about 250 nm and about 300 nm, between about 300 nm and about 350 nm, between about 350 nm and about 400 nm, between about 450 nm and about 500 nm, between about 500 nm and about 550 nm, or between about 550 nm and about 600 nm.

In some embodiments, the annealed photon absorptive material 106 may absorb between about 0.001 percent and about 100 percent of the radiation, such as between about 0.001 percent and about 5 percent, between about 5 percent and about 10 percent, between about 10 percent and about 15 percent, between about 15 percent and about 20 percent, between about 20 percent and about 25 percent, between about 25 percent and about 30 percent, between about 30 percent and about 35 percent, between about 35 percent and about 40 percent, between about 40 percent and about 45 percent, between about 45 percent and about 50 percent, between about 50 percent and about 55 percent, between about 55 percent and about 60 percent, between about 60 percent and about 65 percent, between about 65 percent and about 70 percent, between about 70 percent and about 75 percent, between about 75 percent and about 80 percent, between about 80 percent and about 85 percent, between about 85 percent and about 90 percent, between about 90 percent and about 95 percent, or between about 95 percent and about 100 percent.

A thickness T_{P} of the annealed photon absorptive material 106 may be between about 10 nm and about 100 nm, such as between about 10 nm and about 20 nm, between about 20 nm and about 30 nm, between about 30 nm and about 40 nm, between about 40 nm and about 50 nm, between about 50 nm and about 60 nm, between about 60 nm and about 70 nm, between about 70 nm and about 80 nm, between about 80 nm and about 90 nm, or between about 90 nm and about 100 nm. In some embodiments, the thickness T_{P} of the annealed photon absorptive material 106 is about 20 nm or about 35 nm. By adjusting the thickness T_{P} of the annealed photon absorptive material 106, internal reflectance of the radiation may be controlled. For instance, a relatively greater thickness of the annealed photon absorptive material 106 may be used to minimize the reflectance of the radiation compared to a relatively lesser thickness. The relatively greater thickness T_{P} of the annealed photon absorptive material 106 may be used to maximize absorbance of the radiation in the annealed photon absorptive material 106 compared to a relatively lesser thickness.

The first transparent material 108 is vertically adjacent (e.g., overlying) to the annealed photon absorptive material 106. The first transparent material 108 may be formed of a single material or of multiple materials. The first transparent material 108 may be formed from and include a silicon material, such as an amorphous silicon material, a polysilicon material, a crystalline silicon material, a silicon oxide material, or a combination thereof. The first transparent material 108 may be formed from and include a silicon oxide material or a tetraethyl orthosilicate (TEOS) material. Alternatively, the first transparent material 108 may include, but is not limited to, aluminum oxide, hafnium oxide, silicon nitride, or a combination thereof. The first transparent material 108 functions to internally reflect the radiation generated by the radiation source. In addition, the first transparent material 108 may be thermally insulative. The energy generated by the radiation source may be contained (e.g., confined) within a portion of the microelectronic device 100 that includes the first transparent material 108.

If the first transparent material 108 includes a single material, the first transparent material 108 may be formed of and include about 100% of the material. If the first transparent material 108 includes more than one material, the first transparent material 108 may be formed of and include between about 0 percent (e.g., 0% w/w) and about 100 percent of each of the amorphous, poly, and crystalline silicon materials, such as between about 0 percent and about 20 percent, between about 20 percent and about 40 percent, between about 60 percent and about 80 percent, and between about 80 percent and 100 percent. For example, the first transparent material 108 may comprise about 50 percent amorphous silicon material, about 30% polysilicon material, and about 20% crystalline silicon material, or any other combination of weight percentages of the silicon materials.

A thickness T_{T} of the first transparent material 108 may, independent of the thickness T_{P}, be between about 20 nm and about 250 nm, such as between about 20 nm and about 50 nm, between about 20 nm and about 50 nm, between about 50 nm and about 100 nm, between about 100 nm and about 150 nm, between about 150 nm and about 200 nm, or between about 200 nm and about 250 nm. In some embodiments, the thickness T_{T} may be about 40 nm, about 90 nm, about 120 nm, about 140 nm, or about 200 nm.

In some embodiments, the first transparent material 108 is a TEOS material and the annealed photon absorptive material 106 is a polysilicon material. In other embodiments, the first transparent material 108 is an oxide material (e.g., silicon oxide, hafnium oxide, aluminum oxide, or a combination thereof) and the annealed photon absorptive material 106 is an amorphous silicon material.

In embodiments wherein the additional photon absorptive material 110 is present, the additional photon absorptive material 110 may include one of the materials described above for the annealed photon absorptive material 106. The additional photon absorptive material 110 and the annealed photon absorptive material 106 may exhibit similar or different material compositions as one another. The additional photon absorptive material 110, the first transparent material 108, and the annealed photon absorptive material 106 may exhibit thicknesses independent of each other. For example, the thickness T_{P} of the annealed photon absorptive material 106, a thickness T_{S} of the additional photon absorptive material 110, and the thickness T_{T} of the first transparent material 108 may be about 35 nm, at least about 40 nm, and at least about 60 nm, respectively. More particularly, the thickness T_{T} of the first transparent material 108 may be between about 80 nm and about 100 nm or between about 180 nm and about 200 nm. In some embodiments, the thicknesses T_{P}, T_{S}, T_{T} may be about 20 nm, about 60 nm, and at least about 120 nm, respectively.

The second transparent material 118 may overlie the first transparent material 108 with an interface 120 present between the first transparent material 108 and the second transparent material 118. The interface 120 may exhibit changed properties relative to the first transparent material 108 and the second transparent material 118, such as changes in material morphology. The second transparent material 118 may be substantially planar as formed. However, it is not thus limited and any positive topography of the underlying features may be preserved in the second transparent material 118 as formed, with planarization occurring subsequently. For example, if the positive topography is present following the formation of the second transparent material 118, the second transparent material 118 may subsequently be planarized to exhibit a substantially planar surface. The second transparent material 118 may be formed of and include a material composition similar to the first transparent material 108, such as both of the first transparent material 108 and the second transparent material 118 including a silicon oxide material. The first transparent material 108 and the second transparent material 118 may form the cap structure 119. The interface 120 may include grain boundary differences as the result of separately forming the first transparent material 108 and the second transparent material 118. In addition, an anneal conducted between forming the first transparent material 108 and the second transparent material 118 may contribute to the grain boundary differences.

The microelectronic device 100 may be formed by forming the annealed photon absorptive material 106 on the base material, forming the first transparent material 108 on the annealed photon absorptive material 106, and forming the second transparent material 118 on the first transparent material 108. The annealed photon absorptive material 106, the first transparent material 108, and the second transparent material 118 may be formed on the first region 102 and the second region 104. The additional photon absorptive material 110, if present, may be formed on the second transparent material 118 of the second region 104. The annealed photon absorptive material 106, the first transparent material 108, the second transparent material 118, and the optional additional photon absorptive material 110 may be formed by conventional techniques.

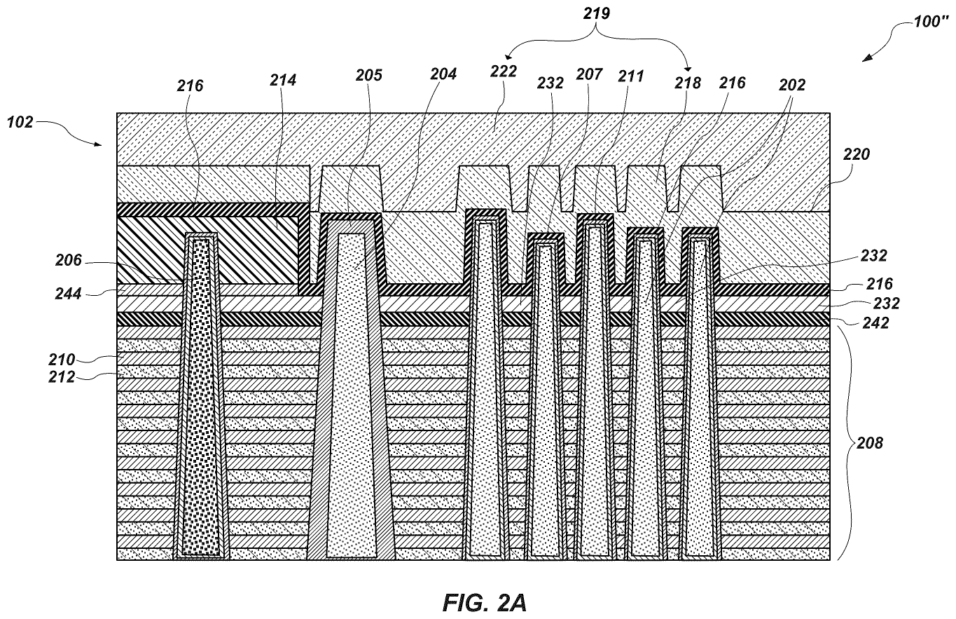

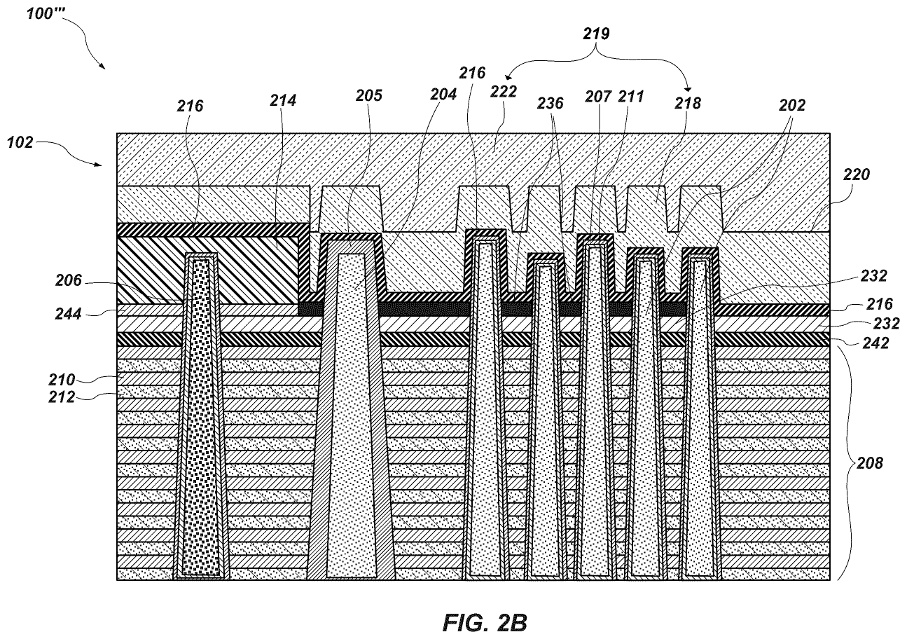

Microelectronic devices 100″, 100′″ according to embodiments of the disclosure are shown in FIGS. 2A and 2B. The microelectronic devices 100′, 100′″ include the first region 102 (e.g., an array region) including one or more features therein. The first region 102 may include the base material or other construction (not shown) upon which one or more materials, such as a stack 208 of tiers of alternating materials 210, 212, are formed. By way of non-limiting example, the alternating materials 210, 212 may be formed of and include conductive materials, dielectric materials, or semiconductive materials. For example, the material 210 may be a conductive material and configured as source-side select gate (SGS), word lines, etc., and the material 212 may be a dielectric material. The microelectronic devices 100″, 100′″ also include a second region 104 laterally adjacent to the first region 102. However, the second region 104 is not illustrated in FIGS. 2A and 2B and subsequent drawings for simplicity and convenience. Only the first region 102 and vertically adjacent materials are shown for simplicity and convenience.

The first region 102 may include one or more features including but not limited to, an array of memory pillars 202, a polysilicon pillar 204 (e.g., polysilicon slot), a contact pillar 206 in electrical contact with a contact structure 214, and alternating materials 210, 212, as shown in FIGS. 2A and 2B. However, other features may be present in the first region 102 depending on performance properties of an electronic device that contains the microelectronic device 100″, 100′″. The pillars 202, 204, 206 vertically extend through the stack 208. Upper portions of the pillars 202, 204, 206 may vertically extend above an upper portion of the stack 208 in an opposite direction to bottom portions of the pillars 202, 204, 206, which extend through the stack 208. In other words, the upper portions of the pillars 202, 204, 206 extend above the stack 208. An upper portion of the contact pillar 206 may extend through materials 232, 242 and 244 and into the contact structure 214. Materials 232 and 242 are vertically adjacent to stack 208. The features of the first region 102 may extend different heights above the stack 208, producing a positive topography.

An annealed photon absorptive material 216′ may be vertically adjacent to (e.g., over) and between the upper portions of the features (e.g., 202, 204, 214). The positive topography of the underlying features (e.g., 202, 204, 214) may be maintained in the photon absorptive material 216. The annealed photon absorptive material 216′ may be similar to the annealed photon absorptive material 106 in FIGS. 1A and 1B, with similar properties (e.g., material composition, thickness, etc.) as described previously for the annealed photon absorptive material 106. The annealed photon absorptive material 216′ may be formed of a photon absorptive material formulated to absorb energy of radiation at a desired wavelength and convert the radiation energy to thermal energy as described previously for the annealed photon absorptive material 106. The thermal energy anneals the photon absorptive material to form the annealed photon absorptive material 216′.

A first transparent material 218 may be vertically adjacent to annealed photon absorptive material 216′. The first transparent material 218 may form a cap on the annealed photon absorptive material 216′ through which underlying features (e.g., pillars 202, 204, 206) of the microelectronic devices 100″, 100′″ may be annealed. The first transparent material 218 may form a portion of a cap structure 219 on the annealed photon absorptive material 216′. The first transparent material 218 may be similar to the first transparent material 108 in FIGS. 1A and 1B, with similar properties (e.g., material composition, thickness, etc.) as described previously for the photon absorptive material 106. The positive topography of the features and the annealed photon absorptive material 216′ may be maintained in the first transparent material 218.

A second transparent material 222 may overlie the first transparent material 218, with an interface 220 between the first transparent material 218 and the second transparent material 222. The interface 220 may exhibit changed properties, such as changes in material morphology, relative to the first transparent material 218 and the second transparent material 222.

The second transparent material 222 and the first transparent material 218 may be formed of and include a similar material composition, such as both of the first transparent material 218 and the second transparent material 222 including a silicon oxide material. The second transparent material 222 may form the cap structure 219 in combination with the first transparent material 218. As described above for the interface 120, the interface 220 may include grain boundary differences as the result of separately forming the second transparent material 222 and the first transparent material 218. In addition, the anneal conducted between forming the first transparent material 218 and forming the second transparent material 222 may contribute to the grain boundary differences. With both the first transparent material 218 and the second transparent material 222 vertically adjacent to (e.g., overlying) the annealed photon absorptive material 216′, the positive topography of the features may be maintained (e.g., preserved) since minimal changes subsequently occur in the positive topography of the features.

As shown in FIG. 2B, according to some embodiments of the disclosure, the microelectronic device 100′″ may include filled portions 236. The filled portions 236 extend between the features (e.g., 202, 204, 214) and include a material composition similar to the annealed photon absorptive material 216′.

Accordingly, a microelectronic device is disclosed and comprises a first region adjacent to a second region. The first region comprises an array region and the second region comprises a non-array region. An annealed photon absorptive material is adjacent to the first region and the second region. A first transparent material is vertically adjacent to the annealed photon absorptive material and a second transparent material is vertically adjacent to the first transparent material. An interface between the first transparent material and the second transparent material exhibits grain boundary differences.

Accordingly, a memory device is disclosed and comprises an upper region comprising an array of memory pillars extending from a first transparent material and into a stack comprising alternating conductive materials and dielectric materials that are vertically adjacent to the first transparent material. A lower region comprises a non-array region and is vertically adjacent to the upper region. The non-array region comprises a CMOS region, a peripheral region, a registration mark region, or a scribe region. An annealed photon absorptive material is vertically adjacent to the memory pillars of the upper region. A cap structure is vertically adjacent to the photon absorptive material. The cap structure comprises the first transparent material and a second transparent material vertically adjacent to the first transparent material and exhibits multicrystalline materials.

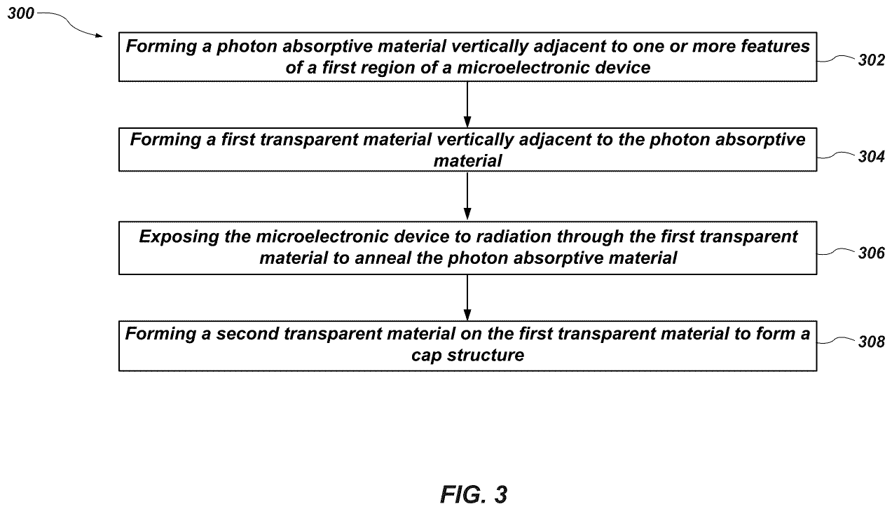

FIG. 3 illustrates a simplified flow diagram of a method 300 of forming the microelectronic devices 100, 100′, 100″, 100′″. The method 300 may comprise act 302 including forming a photon absorptive material vertically adjacent to one or more features (e.g., memory pillars, contact structures, etc.) of a first region of a microelectronic device. Act 304 of the method 300 includes forming a first transparent material vertically adjacent to the photon absorptive material. Act 306 of the method 300 includes exposing the microelectronic device to radiation (e.g., laser emission) through the first transparent material to anneal the photon absorptive material. Act 308 of the method 300 includes forming a second transparent material on the first transparent material to form a cap structure.

The methods of forming the microelectronic devices 100, 100′, 100″, 100′″ according to embodiments of the disclosure may improve the annealing of materials of the microelectronic devices 100, 100′, 100″, 100′″, which increases conductivity in the microelectronic devices 100, 100′, 100″, 100′″. Moreover, the methods of forming the microelectronic devices 100, 100′, 100″, 100′″ according to embodiments of the disclosure may facilitate forming air gaps within the annealed photon absorptive materials (e.g., annealed photon absorptive materials 106, 216′), which increases conductivity in the microelectronic devices 100, 100′, 100″, 100′″. Additionally, the first transparent material 218 forms a cap on the photon absorptive material which advantageously prevents reflow of the photon absorptive material over the features (e.g., 202, 204, 214) and in openings 224 between adjacent features when annealing. This preserves a topography of features in the first region 102 (e.g., array region) of the microelectronic device 100, 100′, 100″, 100′″.

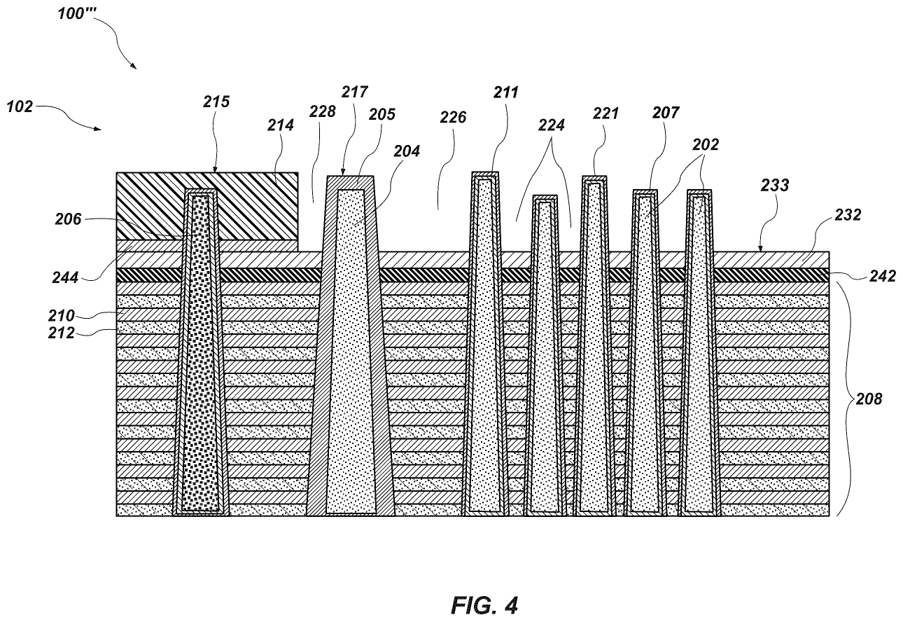

FIGS. 4, 5A, 5B, 6, and 7 illustrate partial cross-sectional views of the microelectronic device 100″, 100′″ during process stages of the method 300. FIG. 4 illustrates the first region 102 of the microelectronic device 100″, 100′″ at an initial process stage on which acts of the method 300 are performed. The second region 104 is not illustrated in FIGS. 4-7 for simplicity and convenience. The first region 102 includes features such as those described above and may be formed by conventional techniques, with openings 224 between adjacent features. The contact pillar 206, the polysilicon pillar 204, and the memory pillars 202 may, for instance, extend above the stack 208. The polysilicon pillar 204 and the memory pillars 202 may be spaced apart by openings 226 and the polysilicon pillar 204 and the contact structure 214 may be spaced apart by additional openings 228. The openings 224, 226, 228 may be defined by sidewalls of the features and exposed horizontal surfaces 233 of materials 232 above the stack 208. Dimensions of the openings 224, 226, 228 may vary depending on the configuration of the microelectronic device being formed and desired performance properties. The dimensions of the openings 224, 226, 228 may or may not be substantially the same as one another depending on the features in the first region 102.

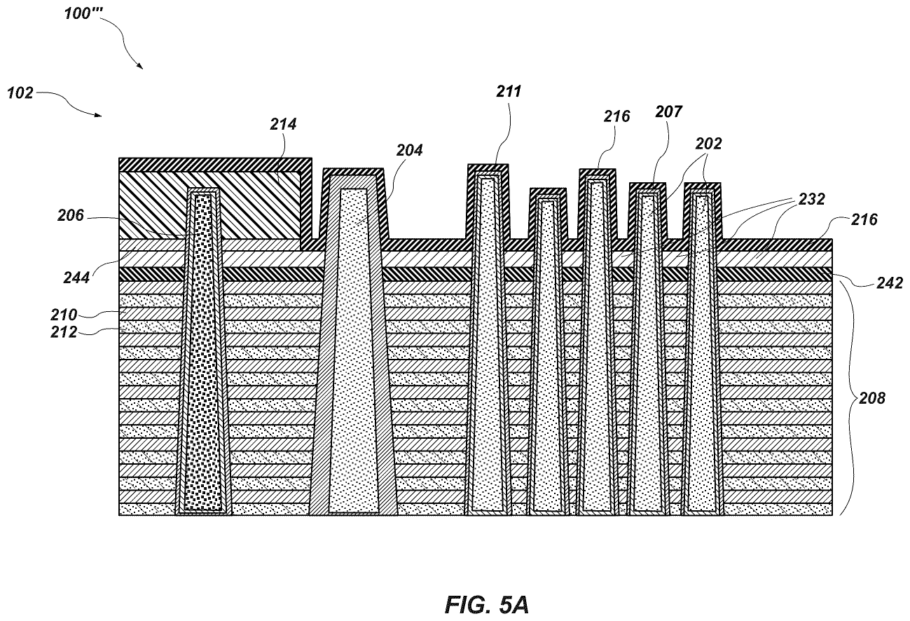

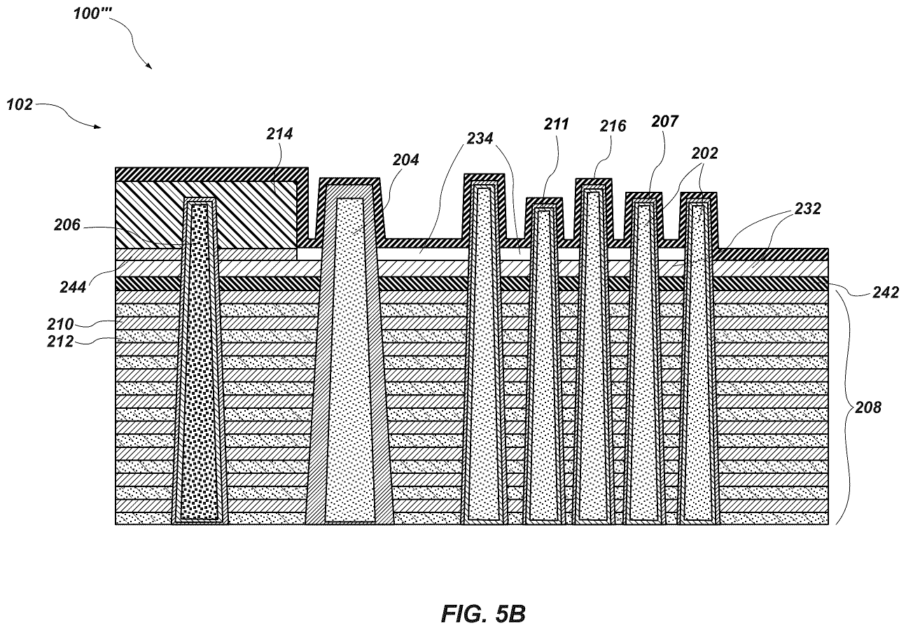

With reference to FIGS. 4, 5A and 5B, act 302 may include forming (e.g., depositing) a photon absorptive material 216 vertically adjacent to one or more features (e.g., 202, 204, 214) of the first region 102 of a microelectronic device (e.g., 100″ or 100′″). The photon absorptive material 216 may also be formed on the second region 104 as shown in FIGS. 1A and 1B. The photon absorptive material 216 may partially fill a volume of the openings 224, 226, 228. The photon absorptive material 216 is vertically adjacent to and conformally formed on the features (e.g., 202, 204, 214) and within the openings 224, 226, 228 in the first region 102. The annealed photon absorptive material 216′ may be conformally formed on sidewalls and horizontal surfaces of the exposed features (e.g., 202, 204, 214) as shown in FIGS. 5A and 5B. In some embodiments, other materials (e.g., liners) may be present between the photon absorptive material 216 and the features. For example, the photon absorptive material 216 may be conformally formed on a liner material 205 adjacent to the polysilicon pillar 204 and a liner material 207 adjacent to the memory pillars 202. A liner material 211 may be between pillars 202 and the liner material 207. The photon absorptive material 216 may be conformally formed on horizontal surfaces 215 of the contact structure 214, horizontal surfaces 217, 221 of the liner materials 205, 207, and horizontal surfaces 233 of the materials 232 overlying the stack 208. If the openings 224, 226, 228 are relatively large and the as-formed thickness of the photon absorptive material 216 is relatively thin, the photon absorptive material 216 may be conformally formed in the openings 224, 226, 228 without pinching off the openings 224, 226, 228, as shown in FIG. 5A.

Depending on the dimensions of the openings 224, 226, 228 and a thickness of the as-formed photon absorptive material 216, the photon absorptive material 216 may pinch off in the openings 224, 226, 228, as shown in FIG. 5B, producing voids 234 below the photon absorptive material 216. The voids 234 (e.g., unfilled portions) below the photon absorptive material 216 may form air gaps below (e.g., underneath) the photon absorptive material 216 and above the stack 208.

The photon absorptive material 216 may be formed by conventional techniques, such as by ALD or CVD. Silicon precursors and dopant (e.g., phosphorous, boron, germanium, gallium, arsenic, carbon, lanthanum, etc.) precursors may be sequentially introduced, in situ, to form a doped photon absorptive material, such as phosphorous doped polysilicon. Alternatively, the dopant precursor may be introduced into a gas phase during CVD growth of the photon absorptive material 216 or the dopants may be implanted, ex situ, in the photon absorptive material 216 utilizing, for example an ion implantation process. An initial concentration of the dopant material (e.g., phosphorous) in the photon absorptive material 216, before an annealing act according to methods of the disclosure is performed, may be between about 8×10²⁰ atoms/cm² and about 10×10²⁰ atoms/cm².

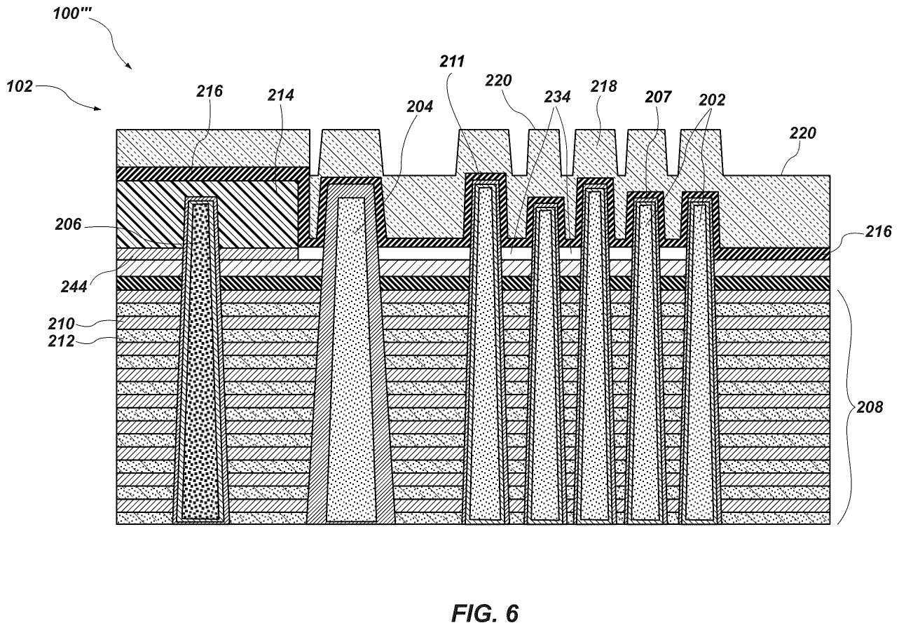

With reference to FIGS. 5A, 5B, and 6, act 304 may include forming the first transparent material 218 vertically adjacent to the photon absorptive material 216. The first transparent material 218 may be conformally formed on the photon absorptive material 216, maintaining the topography of the underlying features (e.g., pillars 202). The first transparent material 218 may also substantially completely fill the remaining volume of the openings 224, 226, 228. The first transparent material 218 may form a cap on the photon absorptive material 216.

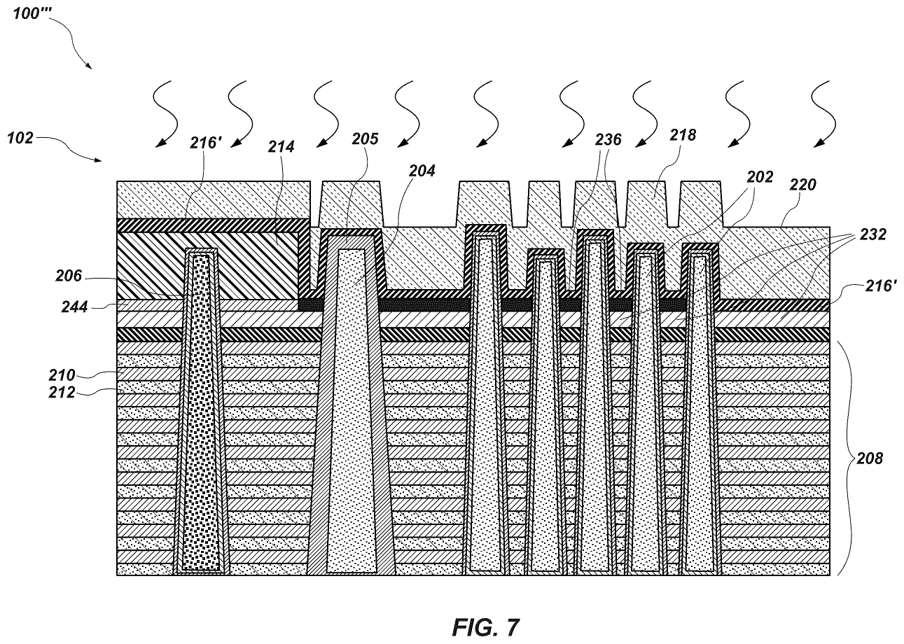

With reference to FIGS. 6 and 7, act 306 may include exposing the microelectronic device to radiation through the first transparent material 218 to anneal the photon absorptive material 216. The photon absorptive material is indicated in FIG. 7 as 216′. Radiation propagates through the first transparent material 218 and is absorbed by the photon absorptive material 216. In particular, the radiation penetrates into the first transparent material 218 and propagates by internally reflecting in the first transparent material 218 and then absorbs into the photon absorptive material 216. Upon absorption, radiation energy is converted to thermal energy and results in a temperature increase in an upper portion of the microelectronic device (e.g., upper portions of the pillars 202, the photon absorptive material 216, etc.). The radiation may be produced by a laser at a wavelength that is sufficient to anneal the photon absorptive material 216 through the cap.

A portion of the radiation may also be absorbed by an upper surface of the first transparent material 218, which may result in a change of the morphology of the first transparent material 218 at the interface 220. The upper surface may form an interface 220 between the first transparent material 218 and the second transparent material 222. In embodiments wherein the first transparent material 218 comprises a silicon material, the morphology of the interface 220 may be, for example, an amorphous silicon, polysilicon, crystalline silicon, or a combination thereof.

An energy density of the radiation absorbed in the photon absorptive material 216 may not predictably correlate (e.g., linearly, exponentially, etc.) with the thicknesses of the photon absorptive material 216, the first transparent material 218. For example, increasing or decreasing the thickness of the first transparent material 218 may not necessarily result in minimization or maximization of absorption of the radiation in the photon absorptive material 216. The thicknesses of the materials may be adjusted relative to each other to obtain a desired amount of absorption in the photon absorptive material 216. By way of non-limiting example, absorption of the radiation in the photon absorptive material 216 is a function of multiple factors, such as the refractive indexes of the first transparent material, 218, the radiation wavelength, the thickness T_{P}, the thickness T_{T}, the radiation frequency, a size of the features (e.g., sizes of the upper and lower portions of the memory pillars 202), and a distance between neighboring features (e.g., 202, 204, 206, 214). To adjust the absorption of the radiation in the photon absorptive material 216 to a desired amount, these parameters may be adjusted relative to each other.

By way of non-limiting example, energy of the radiation per surface area of the microelectronic devices 100″, 100′″, for example on the first region 102, may be between about 0.2 J/cm² and about 2 J/cm², such as between about 0.2 J/cm² and about 0.4 J/cm², between about 0.4 J/cm² and about 0.6 J/cm², between about 0.6 J/cm² and about 0.8 J/cm², between about 0.8 J/cm² and about 1.0 J/cm², between about 1.0 J/cm² and about 1.2 J/cm², between about 1.2 J/cm² and about 1.4 J/cm², between about 1.4 J/cm² and about 1.6 J/cm², between about 1.6 J/cm² and about 1.8 J/cm², or between about 1.8 J/cm² and about 2.0 J/cm².

The radiation used to anneal the photon absorptive material 106, 216 through the first transparent material 108, 218 may include multiple wavelengths between about 100 nm and about 600 nm, such as between about 100 nm and about 150 nm, between about 150 nm and about 200 nm, between about 200 nm and about 250 nm, between about 250 nm and about 300 nm, between about 300 nm and about 350 nm, between about 350 nm and about 400 nm, between about 450 nm and about 500 nm, between about 500 nm and about 550 nm, or between about 550 nm and about 600 nm. In some embodiments, the radiation may comprise multiple wavelengths between about 300 nm and about 310 nm. The radiation may comprise a wavelength of about 308 nm. In other embodiments, the radiation may comprise multiple wavelengths between about 140 nm and about 160 nm. The radiation may comprise a wavelength of about 154 nm.

A duration of the exposure to the radiation to achieve the anneal may be between about 20 ns and about 300 ns, such as between about 20 ns and about 60 ns, between about 60 ns and about 100 ns, between about 100 ns and about 140 ns, between about 140 ns and about 180 ns, between about 180 ns and about 220 ns, between about 220 ns and about 260 ns, or between about 260 ns and about 300 ns.

An increase in the temperature of the photon absorptive material 216 may cause the photon absorptive material 216 to flow and fill in unfilled portions (e.g., voids 234) if present. Filled portions 236 (e.g., annealed fill portions) are shown in FIG. 7 as solid black for enhanced visualization and are formed of and include the same material as the photon absorptive material 216.

The increased temperature within the photon absorptive material 216 may cause a dopant (e.g., phosphorus) in the photon absorptive material 216 to diffuse into underlying features, such as the memory pillars 202. The dopant may also diffuse to a word line in the stack 208. A depth D_{D} of diffusion of the dopant may be between about 0 nm and about 130 nm, such as between about 0 nm and about 20 nm, between about 20 nm and about 40 nm, between about 40 nm and about 60 nm, between about 60 nm and about 80 nm, between about 80 nm and about 100 nm, between about 100 nm and about 120 nm, or between about 120 nm and about 140 nm.

With reference to FIGS. 2A, 2B, and 7, act 308 may include forming a second transparent material 222 on the first transparent material 218 to form the cap structure 219. The second transparent material 222 may be formed by conventional techniques. The second transparent material 222 may substantially or completely fill spaces present between the positive topology of the first transparent material 218. The second transparent material 222 may function as another cap on the first transparent material 218 with the interface 220 between the first transparent material 218 and the second transparent material 222. The second transparent material 222 may subsequently be planarized. Any conventional method may be used, including but not limited to chemical-mechanical planarization (CMP).

The annealing (e.g., laser annealing) may increase dopant activation in the memory pillars 202, reduce roughness of the first transparent material 218 and the photon absorptive material 216, as well as preserve the positive topography of the underlying features. The annealing may also densify oxide materials in the microelectronic device 100″, 100′″, such as when the first transparent material 218 and/or the second transparent material 222 are formed of silicon oxide, increasing the oxide material quality. By conducting the annealing before forming the second transparent material 222, the first transparent material 218 is densified and exhibits a high quality. The interface 220 may be present between the first transparent material 218 and the second transparent material 222 due to different densities of the first transparent material 218 and the second transparent material 222.

Accordingly, a method of forming a microelectronic device is disclosed. The method comprises forming a photon absorptive material vertically adjacent to one or more features of a first region of a microelectronic device. A first transparent material is formed vertically adjacent to the photon absorptive material. The microelectronic device is exposed to radiation through the first transparent material to anneal the photon absorptive material. A second transparent material is formed on the first transparent material to form a cap structure.

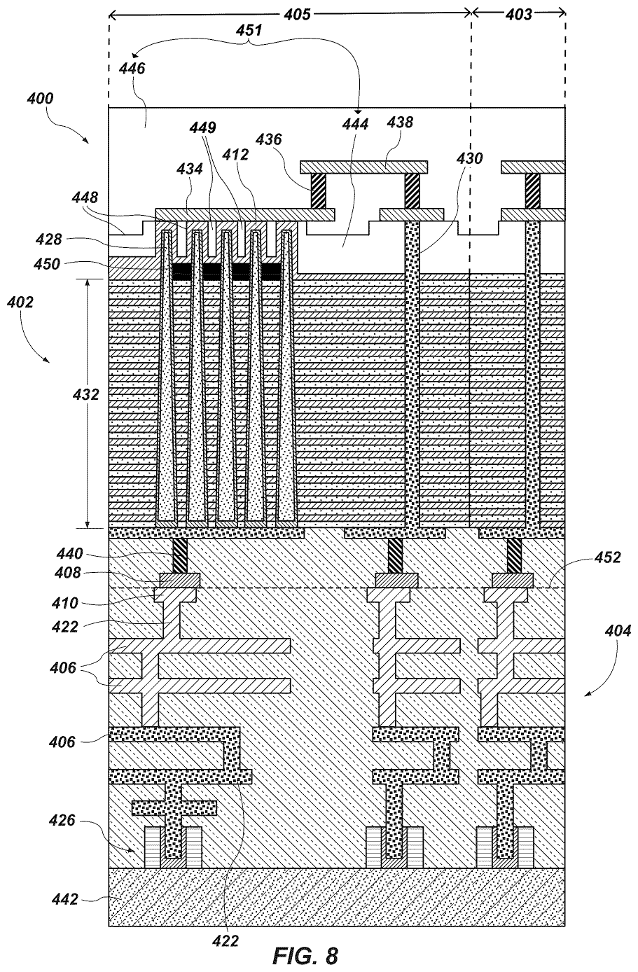

With reference to FIGS. 1A, 1B, 2A, 2B, and 8, the microelectronic devices 100, 100′, 100″, 100′″ may form a portion of a microelectronic device 400 (e.g., a memory device). As shown in FIG. 8, the microelectronic device 400 includes first region 403 (e.g., array region) and second region 405 in an upper region 402 of the microelectronic device 400, which are respectively analogous to the first region 102 and the second region 104 of the microelectronic devices 100, 100′, 100″, 100′″ as shown in FIGS. 1A, 1B, 2A, 2B. The first region 403 may include an array of pillars 428 (e.g., memory pillars), one or more channels 430, one or more contact structures (not shown), one or more polysilicon pillars (not shown), etc. The pillars 428, the contact structures, and the polysilicon pillars may correspond to the pillars 202, contact structures 214, and polysilicon pillars 204 of the microelectronic devices 100″, 100′″. FIG. 8 is a partial illustration of the microelectronic device 400 and illustrates only a portion of the microelectronic device 400 according to embodiments of the disclosure, with additional features omitted for convenience and simplification. Lower portions of the pillars 428 and the channels 430 may extend vertically through a stack 432 of materials (e.g., conductive materials, semiconductive materials, dielectric materials). Upper portions of the pillars 428 and the channels 430 may be adjacent to (e.g., vertically adjacent to) the stack 432. First conductive lines 434 may be vertically adjacent to the pillars 428 and in electrical connection therewith. The first conductive lines 434 may be configured as bitlines. The channels 430 may be in an electrical connection with the pillars 428 through contacts 436 and second conductive lines 438. The microelectronic device 400 may be a portion of a NAND device, a dynamic random access memory (DRAM) device, or other memory device.

The upper region 402 of the microelectronic device 400 is vertically adjacent to a lower region 404. The lower region 404 may be a non-array region, such as a CMOS region, a peripheral region, a registration mark region, or a scribe region. The upper region 402 and the lower region 404 may respectively include pads 408, 410 bonded (e.g., hybrid bonded) to one another. The pads 408 may be in electrical connection with the pillars 428 through contacts 440. The lower region 404 may include conductive lines (e.g., 406), contacts (e.g., 422) in electrical connection with the pads 410 and a gate structure 426 in the lower region 404. The pads 408 may be formed of, for example but not limited to, copper (Cu) or any other conductive material. The lower region 404 may be vertically adjacent to a base material 442 having one or more materials, layers, structures, or regions formed thereon or therein. FIG. 8 shows exemplary configurations of components of the upper region 402 and the lower region 404 of the microelectronic device 400. However, additional configurations of the components of the microelectronic device 400 are contemplated.

With reference to FIGS. 2A and 8, an annealed photon absorptive material 412 may be vertically adjacent to (e.g., directly adjacent to) the stack 432 and extend between the features (e.g., between upper portions of the pillars 428). The annealed photon absorptive material 412 may correspond to the annealed photon absorptive material 216′. For example, portions of the annealed photon absorptive material 412 may be laterally adjacent to the sidewalls of the upper portions of the pillars 428 and extend therebetween. Additional portions of the annealed photon absorptive material 412 may be vertically adjacent to horizontal surfaces of the features (e.g., pillars 428). Materials (not shown), corresponding to materials 232 and 242, may be between the annealed photon absorptive material 412 and the stack 432. Liners (not shown), corresponding to the liner materials 207, 211, may be between the annealed photon absorptive material 412 and the pillars 428.

With reference to FIGS. 2B and 8, the annealed photon absorptive material 412 may be vertically adjacent to filled portions 450 and extend between the features (e.g., between the upper portions of the pillars 428). The filled portions 450 correspond to the filled portions 236 of the microelectronic device 100″. For example, portions of the annealed photon absorptive material 412 may be laterally adjacent to the sidewalls of the upper portions of the pillars 428 and extend therebetween. Additional portions of the annealed photon absorptive material 412 may be vertically adjacent to horizontal surfaces of the features (e.g., pillars 428).

A first transparent material 444 may be vertically adjacent to the stack 432. Upper portions of the features (e.g., pillars 428, channels 430) may extend into the first transparent material 444. Portions 449 of the first transparent material 444 may be contained between sidewalls and horizontal portions of the annealed photon absorptive material 412. The first transparent material 444 may correspond to the first transparent material 218. A second transparent material 446 may be vertically adjacent to (e.g., overlying) the first transparent material 444 and may include the second conductive lines 438, the contacts 436, and the bitlines 434. The second transparent material 446 may correspond to the second transparent material 222.

An interface 448 between the first transparent material 444 and the second transparent material 446 may include grain boundary differences as described for interface 220. For example, the grain boundary difference may be formed of an amorphous silicon material, a polysilicon material, a crystalline material, or a combination thereof. The interface 448 may correspond to the interface 220. A topography of the interface 220 may preserve a topography of the features (e.g., pillars 428). For example, vertical portions of the interface 448 may be vertically adjacent to (e.g., below) the bitlines 434 and laterally adjacent to the sidewalls of the upper portion of the pillars 428. Horizontal portions of the interface 448 may be vertically adjacent to (e.g., below) the bitlines 434 and extend between the sidewalls of the upper portion of the pillars 428. The interface 448 may extend continuously or discontinuously between the first transparent material 444 and the second transparent material 446 in the upper region 402 of the microelectronic device 400. Portions of the first transparent material 444 may, however, be removed using, for example, a wet etch process or a chemical-mechanical polish (CMP) process before forming the features (e.g., bitlines 434, contacts 436), which may result in the interface 448 being discontinuous.

The first transparent material 444 and the second transparent material 446, having the interface 448 in between, may form a multicrystalline, cap structure 451 in that the morphology of one or more of the first transparent material 444, the second transparent material 446, and the interface 448 may differ from one another.

Exposure of the first transparent material 444 to radiation, during an anneal act conducted in the fabrication of the microelectronic device 400, results in an increase in temperature of the upper portions of the microelectronic device 400, such as an increase in temperature of the upper portions of the features (e.g., pillars 428). Upper portions of the upper region 402 may reach temperatures as high as about 1000 °C while lower portions of the microelectronic device 400 (e.g., an interface 452 between the upper region 402 and the lower region 404) may be at lower temperatures. The temperature of the lower portions of the microelectronic device 400 may, for example, be between about 0 °C and about 450 °C, between about 20 °C and about 450 °C, between about 20 °C and about 400 °C, between about 20 °C and about 300 °C, between about 20 °C and about 200 °C, or between about 20 °C and about 100 °C Lower temperatures of the lower portions of the microelectronic device 400 may also be contemplated, such as a cryogenic temperature (e.g., below about-100 °C, below about-150 °C). The localized increase in temperature in the upper portions of the microelectronic device 400 results in the annealed photon absorptive material 412 flowing and filling in unfilled portions between the features and forming filled portions 450. Solid black is used to represent filled portions 450 for enhanced visualization. The filled portions 450 are formed of and include the same material as the annealed photon absorptive material 412. The first transparent material 444 preserves the positive topography of the pillars 428.

Conventionally, to anneal a silicon material formed between and vertically adjacent to features (e.g., an array of memory pillars, polysilicon pillars, contact structure, etc.) of a conventional microelectronic device (e.g., DRAM, NAND) lacking a structure corresponding to the cap structure, the entire microelectronic device is heated to a temperature that makes possible the annealing of the silicon material. Alternatively, a silicon material is formed on the features and then the conventional microelectronic device is exposed to radiation (e.g., laser) such that the radiation directly impacts the silicon material. These conventional methods result in overheating of the entire, conventional microelectronic device because the microelectronic device is necessarily exposed to higher amounts of radiation to achieve a desired annealing temperature. The overheating of the microelectronic device results in damage of any heat-sensitive components of the device. For example, overheating the pads 408, 410 may result in formation of voids in the pads.

In contrast, exposing the microelectronic device 400 to radiation (e.g., laser) according to methods of the disclosure locally increases the temperature of the upper portions of the microelectronic device 400 relative to the temperature of the lower portions such that a temperature gradient is achieved along a length of the microelectronic device 400. This locally increased temperature of the upper portion of the microelectronic device 400 advantageously eliminates the need to heat the entire microelectronic device 400 when annealing the photon absorptive material 412. As a result, damage to the components of the microelectronic device 400, such as pads 408, 410, is reduced because the components are not overheated. Similar advantages are achieved for microelectronic devices 100, 100′, 100″, 100′″.

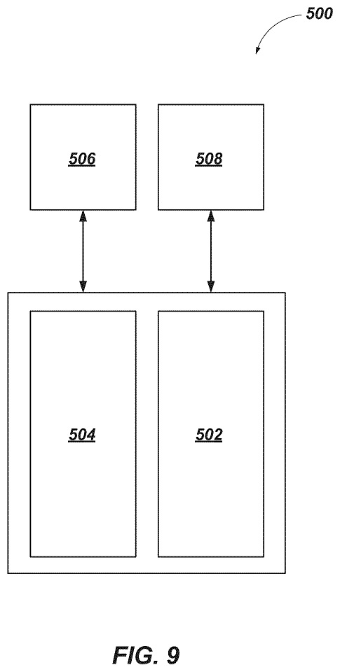

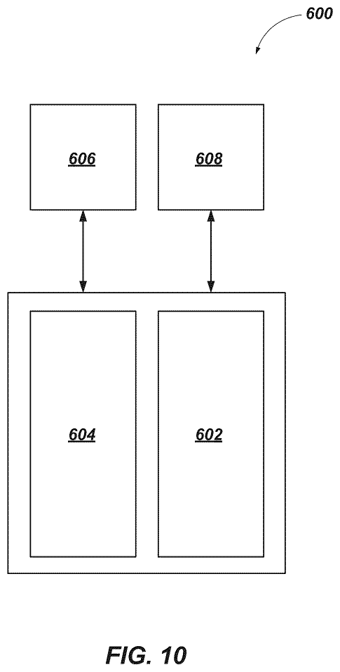

With reference to FIGS. 9 and 10, the microelectronic device 400 may be a portion of a NAND device, a DRAM device, or other memory device. The microelectronic device 400 including one or more of the microelectronic devices 100, 100′, 100″, 100′″ may be, for example but not limited to, a portion of a DRAM device of an electronic system 500 or a portion of a NAND device of an electronic system 600, in accordance with embodiments of the disclosure. FIGS. 9 and 10 are simplified block diagrams of the electronic systems 500, 600. The electronic systems 500, 600 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic systems 500, 600 includes one or more memory devices 502, 602. The memory devices 502, 602 may include, for example, an embodiment of a semiconductor device package including one or more of the microelectronic devices previously described herein (e.g., the microelectronic devices 100, 100′, 100″, 100′″ previously described with reference to FIGS. 1-8).

The electronic systems 500, 600 may further include, for example but not limited to, one or more electronic signal processor devices 504, 604 (often referred to as a “microprocessor”). The electronic signal processor devices 504, 604 may, optionally, include an embodiment of one or more of a microelectronic device and a microelectronic device structure previously described herein. The electronic systems 500, 600 may further include one or more input devices 506, 606 for inputting information into the electronic systems 500, 600 by a user, such as, for example, a mouse or other pointing device, a keyboard, a touchpad, a button, or a control panel. The electronic systems 500, 600 may further include one or more output devices 508, 608 for outputting information (e.g., visual or audio output) to a user such as, for example, a monitor, a display, a printer, an audio output jack, a speaker, etc. In some embodiments, the one or more input devices 506, 606 and the one or more output devices 508, 608 may comprise a single touchscreen device that can be used both to input information to the electronic systems 500, 600 and to output visual information to a user. The one or more input devices 506, 606 and the one or more output devices 508, 608 may communicate electrically with one or more of the memory devices 502, 602 and the one or more electronic signal processor devices 504, 604.

What is claimed is:

1. A microelectronic device, comprising:
a first region adjacent to a second region, the first region comprising an array region and the second region comprising a non-array region;
an annealed photon absorptive material adjacent to the first region and the second region;
a first transparent material vertically adjacent to the annealed photon absorptive material; and
a second transparent material vertically adjacent to the first transparent material, an interface between the first transparent material and the second transparent material exhibiting grain boundary differences.

2. The microelectronic device of claim 1, wherein the first region comprises a stack of tiers of alternating conductive materials and dielectric materials and memory pillars extending from the first transparent material and into the stack.

3. The microelectronic device of claim 2, wherein the memory pillars extend above an upper surface of the stack and a portion of the first transparent material overlies the memory pillars.

4. The microelectronic device of claim 1, wherein an upper surface of the second transparent material is substantially planar.

5. The microelectronic device of claim 2, wherein a portion of the first transparent material is between adjacent memory pillars.

6. The microelectronic device of claim 2, wherein a portion of the first transparent material is vertically adjacent to the memory pillars.

7. The microelectronic device of claim 1, wherein a thickness of the annealed photon absorptive material is between about 10 nm and about 100 nm.

8. The microelectronic device of claim 1, wherein the annealed photon absorptive material comprises a polysilicon material, and the first transparent material and the second transparent material comprise a tetraethoxysilane (TEOS) material.

9. The microelectronic device of claim 1, wherein the annealed photon absorptive material is doped.

10. The microelectronic device of claim 9, wherein a dopant of the photon absorptive material comprises phosphorous, boron, germanium, gallium, arsenic, carbon, or lanthanum.

11. A memory device, comprising:
an upper region comprising an array of memory pillars extending from a first transparent material and into a stack comprising alternating conductive materials and dielectric materials vertically adjacent to the first transparent material;
a lower region comprising a non-array region and vertically adjacent to the upper region, the non-array region comprising a complementary metal oxide semiconductor (CMOS) region, a peripheral region, a registration mark region, or a scribe region;
an annealed photon absorptive material vertically adjacent to the memory pillars of the upper region; and
a cap structure vertically adjacent the photon absorptive material, the cap structure comprising the first transparent material and a second transparent material vertically adjacent to the first transparent material and exhibiting multicrystalline materials.

12. The memory device of claim 11, wherein the non-array region comprises one or more of bond pads, conductive lines, contacts in electrical connection with the pads and a gate structure.

13. A method of forming a microelectronic device, comprising:
forming a photon absorptive material vertically adjacent to one or more features of a first region of a microelectronic device;
forming a first transparent material vertically adjacent to the photon absorptive material;
exposing the microelectronic device to radiation through the first transparent material to anneal the photon absorptive material; and
forming a second transparent material on the first transparent material to form a cap structure.

14. The method of claim 13, wherein exposing the microelectronic device to radiation comprises exposing the microelectronic device to a radiation density between about 0.2 J/cm² and about 2 J/cm².

15. The method of claim 13, wherein exposing the microelectronic device to radiation through the first transparent material comprises increasing a temperature of an upper portion of the microelectronic device.

16. The method of claim 13, wherein exposing the microelectronic device to radiation through the first transparent material comprises increasing the temperature of an upper portion without substantially increasing a temperature of a lower portion of the microelectronic device.

17. The method of claim 13, wherein exposing the microelectronic device to radiation through the first transparent material comprises diffusing a dopant of the photon absorptive material into the one or more features.

18. The method of claim 13, wherein exposing the microelectronic device to radiation through the first transparent material comprises reflecting the radiation within the first transparent material until the radiation is substantially absorbed by the photon absorptive material.

19. The method of claim 13, wherein forming a second transparent material on the first transparent material to form a cap structure comprises forming a grain boundary at an interface between the first transparent material and the second transparent material.

20. The method of claim 13, wherein forming a second transparent material on the first transparent material to form a cap structure comprises forming an interface between the first transparent material and the second transparent material.
